(19) United States
(12) Patent Application Publication
(10) Pub. No.: US 2009/0079510 A1
(43) Pub. Date: Mar. 26, 2009

(54) INTEGRATED CIRCUIT AND RECEIVER OF A GLOBAL POSITIONING SYSTEM (GPS)

(76) Inventor: Meik Wilhelm Widmer, Elchingen (DE)

Correspondence Address: Muncy, Geissler, Olds & Lowe, PLLC, P.O. BOX 1364, FAIRFAX, VA, 22038-1364, US

(21) Appl. No.: 11/850,651

(22) Filed: Sep. 5, 2007

Related U.S. Application Data
(60) Provisional application No. 60/842,041, filed on Sep. 5, 2006.

(51) Int. Cl. H03B 5/32

(52) U.S. Cl. 331/160

(57) ABSTRACT

A Global positioning system and integrated circuit, and a method for starting an associated quartz oscillator with an oscillator circuit that has terminals for a quartz crystal in order to generate a reference signal, and with a status circuit connected to the oscillator circuit, wherein the status circuit has first means for producing a constant operating current of an operating state and a constant starting current of a starting state for the oscillator circuit, the status circuit has second means for producing a quantity dependent on the amplitude of the reference signal, the status circuit has a comparator for comparing the quantity to a switch-on threshold value, and the status circuit has a current switch that is connected to the comparator in such a manner that when the switch-on threshold is exceeded by the quantity, the current switch switches from the starting current to the operating current.

This nonprovisional application claims priority to U.S. Provisional Application No. 60/842,041, which was filed on Sep. 5, 2006, and is herein incorporated by reference.

### BACKGROUND OF THE INVENTION

1. Field of the Invention

The present invention relates to an integrated circuit and a receiver of a global positioning system (GPS) with a quartz oscillator, and a method for starting the quartz oscillator.

2. Description of the Background Art

For a receiver of a global positioning system, it is possible to use as an oscillator type a quartz oscillator that has a high quality factor, for example between 10,000 and 1,000,000.

### SUMMARY OF THE INVENTION

It is an object of the present invention to provide a global positioning system with a quartz oscillator, or an integrated circuit for a quartz oscillator, or a method for starting the quartz oscillator, that reduces phase noise to the greatest extent possible.

Accordingly, an integrated circuit on a semiconductor chip is provided with an oscillator circuit and with a status circuit. In this context, the oscillator circuit has terminals for a quartz crystal in order to generate an oscillator signal. The oscillator circuit is connected to the status circuit, wherein the status circuit can set different states of the oscillator circuit, preferably states that are stable in operation. To this end, the status circuit has first means that are designed to produce a constant operating current of an operating state and, for example, a constant starting current of a starting state for the oscillator circuit. Examples of such means are variable current sources, constant current sources, voltage sources with a series resistor, or the like.

In addition, the status circuit has second means for producing a quantity dependent on the amplitude of the oscillator signal. It is advantageous for this quantity to be a voltage that is dependent on the amplitude of the oscillator signal. Alternatively, a current or frequency, for example, may also be used as the quantity. The status circuit additionally has a comparator for comparing the quantity to a switch-on threshold value. The comparator has a Schmitt trigger or a differential amplifier, for example. The switch-on threshold can be dependent on a threshold voltage of a field-effect transistor or the frequency of an oscillator circuit, for example. However, the switch-on threshold is preferably dependent on a current value of a constant-current source or a voltage value of a constant-voltage source. The state preferably is dependent on the result of the comparison.

The status circuit also has a current switch that is connected to the comparator in such a manner that when a switch-on threshold is exceeded by the quantity, the current switch switches from the starting current to the operating current. Advantageously, the status circuit generates exclusively the operating state and the starting state, but no other state, in order to avoid interference with the oscillation. The current switch is preferably a field-effect transistor, a bipolar transistor or another semiconductor switch that can be switched off.

According to an embodiment, the first means of the status circuit can have a reference current source for generating a reference current for the operating current. Preferably the reference current source is temperature-stable, so that the reference current preferably varies by less than ten percent and the operating current preferably varies by less than twelve percent for operating temperatures that occur. Keeping the currents constant within a short time period helps to minimize phase noise. Over longer time periods, keeping the currents constant achieves a fixed operating point, and hence a constancy of the power converted in the quartz crystal.

In another embodiment, provision is made for the first means of the status circuit to have means for creating a switching current. The switching current here is required for the starting state. In the simplest case, the switching current is obtained from the supply voltage by means of a resistor in that the resistor is connected to a supply voltage terminal. In this variant development, the status circuit also has a summing node for summing the reference current and the switching current. The sum of the reference current and switching current forms the starting current here.

It is advantageous for the starting current in the starting state to be increased by at least a factor of two relative to the operating current in the operating state. It is advantageous for the increase to be in the range of a factor of three to a factor of ten. The starting current is preferably increased by approximately a factor of about eight relative to the operating current in the operating state.

According to another aspect, the second means of the status circuit have a rectifier for producing the quantity. This rectifier preferably rectifies the oscillator signal. To this end, the rectifier can have a diode or a diode bridge, for example. In one possible variant embodiment, the quantity corresponds to the peak value of the rectified signal. However, In another variant, the second means of the status circuit preferably have, in addition, a filter to produce the quantity. This filter is advantageously connected to the rectifier. In this regard, the filter preferably has an integrating element, in the form of a low-pass filter consisting of a resistor and a capacitor, for example.

In another variant, provision is made that the comparator for comparing the quantity additionally has a switch-off threshold value. In this context, the comparator is connected to the current switch such that the current switch switches from the operating current to the starting current when the quantity drops below the switch-off threshold. Thus, if the value drops below the switch-off threshold, the status circuit initiates the starting state again. Subsequently, either the switch-on threshold is exceeded again, or else the supply voltage is disconnected or switched off so that no state is necessary any longer.

According to another variant, the integrated circuit has a reference signal switch that is connected to the comparator such that when the quantity exceeds the switch-on threshold, the oscillator signal is passed through as reference signal by means of the reference signal switch. The reference signal is preferably used as a reference signal for evaluating satellite signals in a global positioning system. The reference signal preferably represents the system clock for a GPS receiver. For this application, this signal has a high coherence over time. The properties of the reference signal influence all GPS-related processes in the receiver, such as tracking and acquisition, for example.

In another aspect of the foregoing development, provision is made that the comparator for comparing the quantity additionally has a switch-off threshold value, wherein the comparator is connected to the reference signal switch such that the reference signal switch blocks the oscillator signal when the quantity drops below the switch-off threshold.

According to another embodiment, the oscillator circuit is differential in design. The oscillator circuit here preferably has at least one current mirror.

In this context, the differential oscillator circuit has two preferably symmetrically designed branches in which the alternating oscillator current is phase-shifted by 180° with respect to one another. The differential oscillator circuit advantageously has the current mirror for setting an operating current through each of the two branches. A current mirror mirrors the current from one mirror branch to one or more additional mirror branches. In this regard, the relationship of the mirror currents to one another is determined by the mirror factor. The operating current determines the operating point of active elements of the oscillator circuit, and thus their electrical characteristics, such as, e.g., their gain. Active elements of the oscillator circuit can be, for example, single transistors or cascodes. In this regard, the mirror ratio in the operating state is preferably not greater than 10:1, so that the mirrored current is no more than ten times the current to be mirrored.

In another variant, the differential oscillator circuit has a first circuit section with the high-frequency oscillator signal. The oscillator signal is an oscillator current and/or an oscillator voltage that has an alternating component at the high oscillator frequency, for example. The integrated components in this first circuit section act as impedances on the amplitude, frequency, and/or phase of the oscillator signal.

In this variant, the differential oscillator circuit additionally can have a second circuit section. The second circuit section is separated from the high frequency oscillator signal in the manner of a decoupling by a number of impedances or by a short circuit of the AC component of the oscillator signal. The effect on the high frequency oscillator signal of impedances resulting from components in this second circuit section can thus be ignored in this variant development. The current switch in this variant development is connected to the second circuit section.

According to an embodiment, the differential oscillator circuit can have two transistors connected to the quartz crystal. The two transistors are junction field effect transistors or MOSFETs or bipolar transistors, for example, and are preferably identical within the scope of manufacturing tolerances.

According to another aspect, provision is made that the two transistors connected to the quartz crystal are part of the current mirror. The transistors are thus operated with a dual function, both as amplifying elements of the differential oscillator circuit with regard to an AC signal of the oscillation and as current sources of the relevant branch of the oscillator circuit with regard to the operating current defined as a DC current. As current sources, they thus define their own operating current and thus the operating point.

According to another aspect, the bases of the two transistors are connected to one another through a number of resistors to set the operating point. The two resistors, each of which is connected to the base of one of the relevant transistors in the relevant branch, are connected together at a connecting node. As a result of the symmetry of the branches of the differential oscillator circuit, this connecting node represents a virtual DC point with respect to the oscillator frequency.

According to an embodiment, each of the two transistors can have at least one resistor connected between emitters and a supply voltage terminal, and each constitutes a mirror branch of the current mirror. The bases of the two transistors are connected to an additional mirror branch of the current mirror by means of the resistors at the bases. The additional mirror branch is preferably designed as part of the second circuit section of the oscillator circuit and can thus be ignored as an impedance in designing the first circuit section for the oscillation of the oscillator circuit.

The embodiments described above are especially advantageous both individually and in combination. In this regard, all variant developments can be combined with each other. Some possible combinations are explained in the description of the example embodiments in the figures. However, the possibilities described there for combinations of the variant developments are not exhaustive.

Another aspect of the invention is a receiver of a global positioning system (GPS). This receiver has an antenna for receiving satellite signals. A receiver circuit of the receiver is connected to the antenna and serves to evaluate the satellite signals. In addition, the receiver has an oscillator circuit that is connected to the receiver circuit and that has terminals for a quartz crystal for generating a high-frequency oscillator signal and, as a function of the oscillator signal, a reference signal for the receiver circuit for evaluation of the satellite signals.

In addition, the receiver can have a status circuit connected to the oscillator circuit, wherein the status circuit can establish different states of the oscillator circuit. Preferably, in this regard each state is associated with an operating point of the oscillator circuit. In advantageous manner, an essentially constant operating current is established by the status circuit in each state to set the operating point associated with the state.

The status circuit has first means for producing a constant operating current of an operating state and a constant starting current of a starting state for the oscillator circuit. The status circuit additionally has second means for producing a quantity dependent on the amplitude of the oscillator signal. The status circuit has a comparator for comparing the quantity to a switch-on threshold value. In addition, the status circuit has a current switch that is connected to the comparator in such a manner that when a switch-on threshold is exceeded by the quantity, the current switch switches from the starting current to the operating current.

The receiver can also be further developed in accordance with the aforementioned aspects.

Another aspect of the invention is a method for starting a quartz oscillator. In this context, the quartz oscillator is initially operated in a starting state with a starting current following switch-on of a supply voltage. A quantity that depends on the amplitude of an oscillator signal is measured and compared with a switch-on threshold value, preferably in an ongoing manner. To change the operating point of an oscillator circuit with the quartz crystal, a switchover preferably takes place from the starting current to a constant operating current for an operating state of the quartz oscillator when the quantity depending on the amplitude of the oscillator signal exceeds the switch-on threshold value. It is advantageous for the method to be carried out with the means of the integrated circuit or of the global positioning system.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic block diagram of a GPS receiver;

FIG. 2 is a schematic block circuit diagram of an oscillator circuit with a quartz crystal and a status circuit; and

FIG. 3 is a schematic detail view of the block circuit diagram from FIG. 2 with a switchable current mirror.

### DETAILED DESCRIPTION

In order to evaluate satellite signals, for example for a navigation device, global positioning systems require as precise a reference signal as possible. For this reason, a global positioning system is particularly susceptible to problems with respect to time jitter or with respect to phase noise in the frequency domain, on account of a time coherent demodulation by means of a correlation method. One requirement for a quartz oscillator is thus to exhibit the smallest possible phase noise. In addition, the oscillator must oscillate reliably under all operating conditions that arise. To this end, the quartz oscillator must thus be operated at an operating point that ensures this. While regulation of the operating current does produce an operating point for the quartz oscillator at which it oscillates reliably, the operating current is continuously changed, wherein the phase noise is significantly increased by this continuous change. The invention solves this problem by, for example, a status circuit, such as is described in the description of the figures below.

In FIG. 1, an example embodiment for a receiver 100 of a global positioning system (GPS) is shown as a schematic block diagram. The receiver 100 has an antenna 140 for receiving satellite signals. The current position, speed, and time are determined from the received satellite signals in a receiver circuit 110 connected to the antenna 140, and are emitted at its output as a signal PVT (position, velocity, time), for example with longitude and latitude for the position. To evaluate the satellite signals, the receiver circuit 110 needs as precise a reference signal Uref as possible from the quartz oscillator 120.

In addition, the receiver 100 has a quartz oscillator 120 and a status circuit 130 for starting the quartz oscillator 120. Quartz crystals for quartz oscillators are known per se and are available in different forms for different oscillator frequencies. The status circuit 130 starts the oscillation of the oscillator 120 in a starting state. After the starting state, the oscillator 120 continues to oscillate in an operating state that follows the starting state.

In this context, the status circuit 130 is designed such that it controls a constant operating point of the quartz oscillator 120 during the operating state, and has no additional effects on the characteristics of the oscillator 120. Moreover, the status circuit 130 must ensure reliable starting of the oscillation of the quartz oscillator 120 under the ambient conditions that arise during the use of the quartz oscillator 120, such as an operating temperature range, a supply voltage range, ranges of characteristics of the components as a function of possible process variations in the manufacture of the components, or the like.

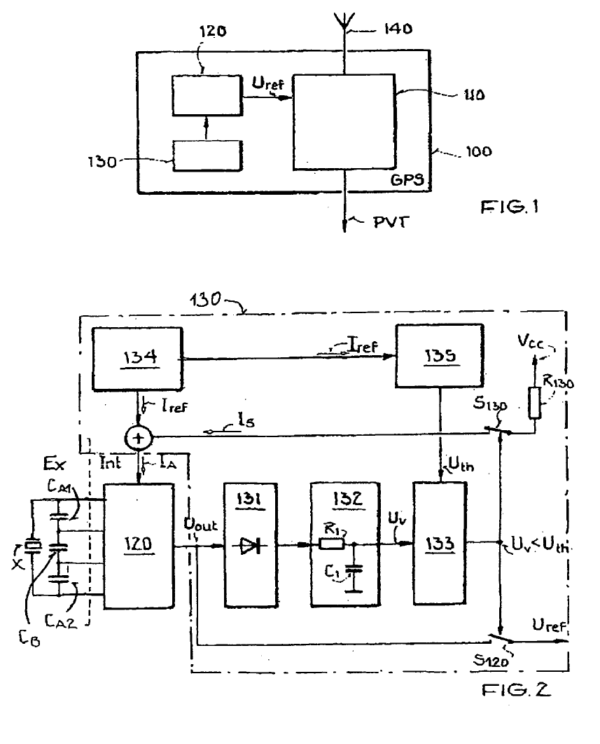

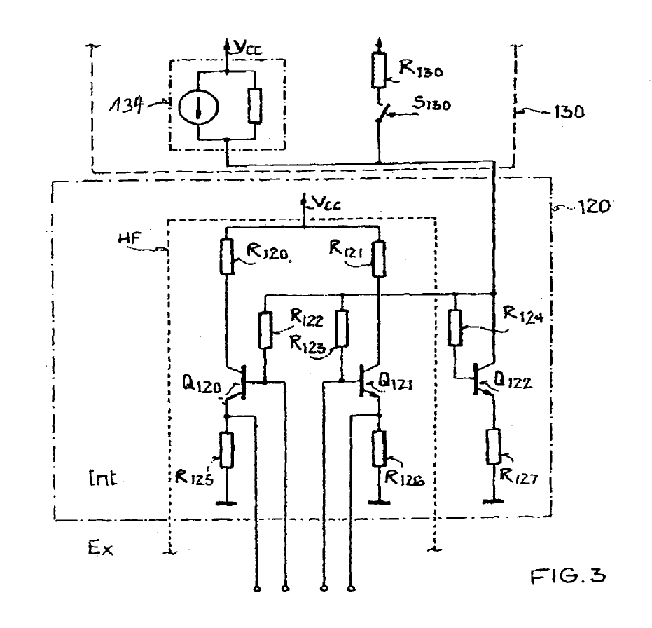

Such a quartz oscillator 120 with a status circuit 130 is shown schematically as a circuit diagram in FIG. 2. In this context, the quartz oscillator 120 and the starting circuit 130 are preferably used in a global positioning system (GPS), as shown in FIG. 1, since this example embodiment has surprising advantages for a global positioning system. Naturally, an oscillator 120 with a status circuit 130, as shown in FIG. 2, can also be used in another device such as a transmitter or receiver—for example for stationary or mobile communication.

The schematic block diagram from FIG. 2 will be explained first. The oscillator circuit 120 is integrated on a semiconductor chip and has terminals for the quartz crystal X and for the capacitors C_{A1}, C_{A2}, and C_{B} that are external to the chip. All functional elements integrated on the semiconductor chip are shown in the integrated region Int in FIG. 2, while external components that are connected to a terminal of the semiconductor chip and are located outside the chip are shown in the external region Ex in FIG. 2. The current I_{A} flowing into the input of the oscillator circuit 120 in the exemplary embodiment in FIG. 2 defines the operating current of the oscillator circuit 120. It is advantageous for the operating current defining the operating point of the oscillator circuit 120 to be proportional to the current I_{A}. The setting of the operating current by means of a current mirror is explained further below with reference to FIG. 3. In this context, the setting of the operating current by means of a current mirror is only one preferred method (best mode) from among many possible implementations. The oscillator circuit 120 additionally has an output at which an oscillator signal Uout is emitted.

The current I_{A} is the sum of the currents Iref and I_{S}, which flow into the summing node. The summing node is represented by a symbol in FIG. 2. The constant current Iref is generated by a temperature-stable constant current source 134. With a closed current switch S130, the switching current I_{S} is generated by the supply voltage Vcc and the resistor R130. In contrast, the current I_{S} assumes the value zero when the current switch S130 is open. The following applies in general:

I_{A}=Iref+I_{S}

The status circuit 130 is intended to bring about two states. In an operating state, only the current I_{A}=Iref is supposed to flow in the oscillator circuit 120 as operating current, thus defining the operating current, and hence the operating point of the oscillator circuit 120. For this operating state, the status circuit 130 brings about an open current switch S130.

In order to start the quartz oscillator reliably, a relatively high operating current is required. Accordingly, in a starting state, the current switch S130 is closed by the status circuit 130, and, as the starting current, the current I_{A} that determines the operating point is increased relative to the operating current by the switching current I_{S}. It is advantageous for the current I_{A} to be increased by at least a factor of two by the switching current I_{S}.

The status circuit 130 has at least the functional elements 131, 132, 133, 134, 135, R130, S130, whose functions for the particular state are described below.

The oscillator signal Uout is rectified in the rectifier 131. To this end, the rectifier can be designed as a half-wave rectifier, for example. The rectified signal is filtered by the filter 132. The filter 132 can take the form of, for example, an integrating element consisting of a resistor R1 and a capacitor C1. The output voltage U_{V} is a quantity which depends on the amplitude of the oscillator signal Uout.

The functional block 133 is a comparator that compares the voltage quantity U_{V} to a switch-on threshold value. The switch-on threshold value here is dependent on a constant voltage Uₜₕ. In the example embodiment from FIG. 2, the switch-on threshold value is identical to the constant voltage Uₜₕ. In the exemplary embodiment from FIG. 2, the comparator also has a switch-off threshold that is lower than the switch-on threshold, and likewise is dependent on the constant voltage Uₜₕ. The comparator of the example embodiment in FIG. 2 is thus designed as a window comparator, which also may be called a Schmitt trigger. The constant voltage Uₜₕ here is obtained from the constant current Iref through a current-to-voltage converter 135.

If a voltage supply of the oscillator circuit 120 and of the state circuit 130 is now switched on, the quartz oscillator does not at first oscillate. Accordingly Uout, and hence U_{V}, is zero at first. Consequently, U_{V} is initially smaller than the switch-on threshold value. This starting state is shown in FIG. 2. In this context, the current switch S130 is closed and a reference signal switch S120 is open. Therefore, in this starting state the current I_{A} is equal to the sum of the currents Iref and I_{S}. The operating current for the oscillator circuit 120 is increased. The quartz oscillator reliably starts to oscillate. Hence the amplitude of the oscillator signal Uout rises.

Along with the rise in amplitude of the oscillator signal Uout the voltage U_{V} also rises, and finally exceeds the switch-on threshold value, given the prerequisite of reliable oscillation of the quartz oscillator. Once the switch-on threshold value is exceeded, the operating state is reached. The current switch S130 is opened and the reference signal switch S120 is closed. Consequently the current I_{A} corresponds to the constant current Iref and is the operating current of the operating state. The switches S130 and S120 are transistors as semiconductor switches, for example, such as field-effect transistors or bipolar transistors. The reference signal switch S120 serves to output the oscillator signal Uout to the receiver circuit 110 as reference signal for evaluating the satellite signals exclusively in the operating state.

The example embodiment shown in FIG. 2 can have the advantages, for example, that the reliability of starting the quartz oscillator is increased without requiring regulation of the operating current. In this context, it is possible to achieve rapid starting, and hence rapid readiness for operation of the global positioning system. The starting of the oscillation can take place independently of influencing factors that arise during operation, for example, such as operating temperature, operating voltage, or production process variation in the components. The status circuit 130 can advantageously be designed here to have no effect on the oscillation of the quartz oscillator 120 in the operating state.

One advantage among many advantages can be that the starting circuit 130 requires no additional current in the operating state, since the functional blocks are assigned an additional function (dual function) in the operating state. Thus, the reference signal switch S120 forms a gate that advantageously only passes an oscillator signal Uout suitable as reference signal Uref. A battery of, for example, a portable GPS is subjected to less of a load in this way. As compared to regulating the operating current of the oscillator 120, the exemplary embodiment of FIG. 2 can exhibit the advantage that jitter, or the phase noise of the oscillator 120, is significantly reduced.

Parts of the oscillator circuit 120 and parts of the status circuit 130 are shown in FIG. 3. The status circuit 130 is surrounded by a dashed line. The oscillator circuit 120 is surrounded by a dotted-and-dashed line. In addition, the oscillator circuit 120 has a first circuit section HF which is composed of components that influence an oscillator signal. This first circuit section HF is surrounded by a dotted line. Components of the oscillator circuit 120 that are important for the oscillation are constructed symmetrically, so that the oscillator circuit 120 is differential in design.

The npn bipolar transistors Q120 and Q121 are each connected in a branch of the differential oscillator circuit 120. The emitter currents through the npn bipolar transistors Q120 and Q121 have a DC component and an AC component, wherein the AC components of the two currents are phase-shifted 180° from one another.

Connected to each base of the npn bipolar transistors Q120 and Q121 is a resistor R122 or R123 that supplies a base current for setting an operating current at an operating point of the npn bipolar transistors Q120 and Q121. The two resistors R122 and R123 are connected to one another, so that an AC component of the base current phase-shifted by 180° is shorted together through this connection. This short circuit forms a virtual ground point with respect to the oscillator signal. Since interfering signals at this point act symmetrically on the differential first circuit section HF of the oscillator circuit 120, this virtual ground point can be used for changing the operating point of the oscillator circuit 120. For a symmetrical construction of the oscillator 120, the resistors R122 and R123, the resistors R125 and R126, and the resistors R120 and R121 are equal in each case. In addition, the npn bipolar transistors Q120 and Q121 equal one another in this regard, and are identical within the scope of manufacturing tolerances.

The oscillator circuit 120 is integrated on a semiconductor chip here. In this context, the integrated region Int has terminals that are routed out of the semiconductor chip into an external region Ex. In this regard, the base terminals and the emitter terminals of the npn bipolar transistors Q120 and Q121 are routed as connections to the terminals of the quartz crystal.

For the purpose of setting the operating point, the transistors Q122, Q120 and Q121, together with the base resistors R122, R123 and R124 and the emitter resistors R125, R126 and R127, constitute a current mirror. In this context, the npn bipolar transistor Q122 and the resistors R124 and R127 are embodied outside the first circuit section HF in a second circuit section of the oscillator circuit 120, and thus are separate from the high frequency oscillation. To set two identical operating currents for identical operating points of the npn bipolar transistors Q120 and Q121, the oscillator has the current mirror. The DC component of the currents through the npn bipolar transistors Q120 and Q121 is set by the current mirror. The following applies to the DC components here:

I_{Q120}=I_{Q121}=k·I_{Q122}

where k is a mirror factor that is less than or equal to 10.

This is achieved in that the npn bipolar transistors Q120, Q121 and Q122 are identical within the scope of manufacturing tolerances. Moreover, the base resistors R122, R123 and R124 are equal. The following applies for the resistors R125, R126 and R127:

R127·k=R126=R125

where k is once again the mirror factor. The current flowing through the resistor R127 and through the npn bipolar transistor Q122 thus flows, magnified by the mirror factor k, through each of the npn bipolar transistors Q120 and Q121 as the operating current, and determines their operating point.

In addition, FIG. 3 shows a part of the status circuit 130. The constant current source 134 is connected in parallel with the series circuit consisting of the resistor R130 and the current switch S130. In this context, the current IA flows through the npn bipolar transistor Q122 and determines the operating point of the oscillator circuit 120 through the current mirror already explained.

In addition to other advantages, the exemplary embodiment from FIG. 3 can exhibit the advantages that the oscillator circuit 120 is designed, by means of the virtual ground point, such that the status circuit 130 has no effect on the oscillation of the quartz oscillator 120 in the operating state. It is advantageous for the constant current source 134 and the current switch S130 to be connected to the virtual ground point, which carries essentially no oscillator AC signal component, and hence has essentially only a DC voltage. For this reason, the constant current source 134 and the current switch S130 preferably do not form parasitic capacitances for the oscillator circuit 120, which otherwise would have to be taken into account in designing the oscillator circuit 120.

Naturally, the invention is not limited to the example embodiments shown, but also includes variant embodiments not shown. For example, bipolar transistors could be used exclusively, or only field-effect transistors could be used. Moreover, it is possible within the scope of the invention to use only one simple comparator and to replace the functionality of the reference signal switch S120 with other hardware or software. It is also possible within the scope of the invention to use other means for producing the starting current or the operating current.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A integrated circuit comprising:
an oscillator circuit that has terminals for a quartz crystal in order to generate an oscillator signal; and
a status circuit connected to the oscillator circuit, the status circuit comprising:
a first component for producing a constant operating current of an operating state and a constant starting current of a starting state for the oscillator circuit;
a second component for producing a quantity dependent on an amplitude of the oscillator signal;
a comparator for comparing the quantity to a switch-on threshold value; and
a current switch connected to the comparator such that when the switch-on threshold is exceeded by the quantity, the current switch switches from the starting current to the operating current.

2. The integrated circuit according to claim 1, wherein the first component of the status circuit has a reference current source for generating a reference current for the operating current.

3. The integrated circuit according to claim 2, wherein the first component of the status circuit create a switching current, and also have a summing node for summing the reference current and switching current for the starting current.

4. The integrated circuit according to claim 1, wherein the second component of the status circuit has a rectifier and/or a filter for producing the quantity.

5. The integrated circuit according to claim 1, wherein the comparator for comparing the quantity additionally has a switch-off threshold value, wherein the comparator is connected to the current switch such that the current switch switches from the operating current to the starting current when the quantity drops below the switch-off threshold.

6. The integrated circuit according to claim 1, wherein the circuit has a reference signal switch that is connected to the comparator such that when the quantity exceeds the switch-on threshold, the oscillator signal is passed through as reference signal by means of the reference signal switch.

7. The integrated circuit according to claim 6, wherein the comparator for comparing the quantity additionally has a switch-off threshold value, wherein the comparator is connected to the reference signal switch such that the reference signal switch blocks the oscillator signal when the quantity drops below the switch-off threshold.

8. The integrated circuit according to claim 1, wherein the starting current in the starting state is increased by at least a factor of two relative to the operating current in the operating state.

9. The integrated circuit according to claim 1, wherein the oscillator circuit is differential in design, and has at least one current mirror.

10. The integrated circuit according to claim 9,
wherein the differential oscillator circuit has a first circuit section with the oscillator signal, and has a second circuit section,
wherein the second circuit section is separated from the oscillator signal in the manner of a decoupling by a number of impedances or by a short circuit of the AC component of the oscillator signal, and
wherein the current switch is connected to the second circuit section or through the summing node.

11. The integrated circuit according to claim 9, wherein the differential oscillator circuit has two transistors connected to the quartz crystal.

12. The integrated circuit according to claim 11, wherein the two transistors connected to the quartz crystal are part of the current mirror.

13. The integrated circuit according to claim 11, wherein the bases of the two transistors are connected to one another through a number of resistors to set the operating point.

14. The integrated circuit according to claim 11, wherein each of the two transistors that has at least one resistor connected between the emitters and a supply voltage terminal constitutes a mirror branch of the current mirror, and wherein the bases of the two transistors are connected to an additional mirror branch of the current mirror by means of the resistors at the bases.

15. A receiver for a global positioning system (GPS), the receiver comprising:
an antenna for receiving satellite signals;
a receiver circuit for evaluating the satellite signals;
an oscillator circuit that is connected to the receiver circuit and that has terminals for a quartz crystal for generating an oscillator signal and, as a function of the oscillator signal, a reference signal for the satellite signals; and
a status circuit connected to the oscillator circuit,
wherein the status circuit has a first component for producing a constant operating current of an operating state and a constant starting current of a starting state for the oscillator circuit,
wherein the status circuit has a second component for producing a quantity dependent on the amplitude of the oscillator signal,
wherein the status circuit has a comparator for comparing the quantity to a switch-on threshold value, and
wherein the status circuit has a current switch that is connected to the comparator in such a manner that when a switch-on threshold is exceeded by the quantity, the current switch switches from the starting current to the operating current.

16. A method for starting a quartz oscillator, the method comprising
operating the quartz oscillator, initially, in a starting state with a starting current following a switch-on of a supply voltage;
measuring a quantity that depends on an amplitude of an oscillator signal;
comparing the quantity with a switch-on threshold value; and
performing a switchover from the starting current to a constant operating current for an operating state of the quartz oscillator when the quantity depending on the amplitude of the oscillator signal exceeds the switch-on threshold value.
